(19) United States
(12) Patent Application Publication
(10) Pub. No.: US 2026/0015224 A1
(43) Pub. Date: Jan. 15, 2026

(54) METHOD FOR MANUFACTURING A VIBRATORY MECHANICAL INERTIAL SENSOR, SENSOR OBTAINED BY SUCH A METHOD AND INERTIAL UNIT INCLUDING SUCH A SENSOR

(71) Applicant: JXSENS, Ecully (FR)

(72) Inventor: José Louis BEITIA, Lyon (FR)

(21) Appl. No.: 19/264,775

(22) Filed: Jul. 9, 2025

(30) Foreign Application Priority Data
Jul. 9, 2024 (FR) 2407479

(51) Int. Cl. B81C 1/00; B81B 3/00; H05K 9/00

(52) U.S. Cl. CPC B81C 1/00206; B81B 3/0021; H05K 9/0075; B81B 2201/025; B81B 2201/0285; B81C 2201/0188

(57) ABSTRACT

A method for manufacturing a vibratory mechanical inertial sensor, sensor obtained by such a method and inertial unit including such a sensor
The invention relates to a method for manufacturing a vibratory inertial sensor (1), comprising a step of associating a test body (3) with a base (2), a step of assembling a cover (100) to said base (2) to form a casing within which said test body (3) is housed, a step of vacuuming said casing or filling the latter with a dry gas, and a step of magnetically shielding said casing that includes a first operation of depositing, by galvanoplasty, a first layer of a first ferromagnetic material on part at least of said casing.
Vibratory inertial sensors

The present invention relates to the general technical field of inertial sensors for measuring movement and orientation, such as, e.g., gyroscope sensors based on Coriolis forces to measure rates of rotation and/or angular positions, such as Coriolis vibratory gyrometers or gyroscopes (CVG, for Coriolis Vibratory Gyroscope), or also vibratory accelerometers (VBA, for Vibrating Beam Accelerometer).

More particularly, the present invention relates to a method for manufacturing a vibratory mechanical inertial sensor, comprising a step of associating a test body with a base, said test body being designed to vibrate and/or deform and/or move, said method further comprising a step of assembling a cover to said base so that said cover covers the test body and forms with the base a casing within which said test body is housed.

The present invention further relates to a vibratory mechanical inertial sensor comprising at least one base, a test body attached to said base and designed to vibrate and/or deform and/or move, as well as a cover that covers said test body and forms with the base a casing that delimits an inner space within which said test body is housed.

Finally, the present invention also relates to an inertial unit including at least one plate as well as at least one vibratory mechanical inertial sensor, said plate being provided with at least one support to which is attached said inertial sensor to be immobilized relative to said plate, said inertial unit further including a cover that covers said vibratory mechanical inertial sensor and is attached to the plate to form with the latter an enclosure within which is housed said vibratory mechanical inertial sensor.

The vibratory mechanical inertial sensors, which implement test bodies intended to vibrate, or to move, or to be deformed, are well known. They are used to provide movement and/or orientation measurements.

In particular, gyroscopes with a vibratory structure are known, which are intended to measure angular velocities. These vibratory gyrometers are based on the Coriolis effect, which causes a vibrating structure, presenting a second-order resonance mode which is divided into a primary mode and a secondary mode, modally orthogonal to each other, to undergo a force, when it rotates, to continue vibrating in a plane that is fixed or partially driven with a known fixed coefficient, in the mode space defined by the primary and secondary modes. Applying an opposite force makes it possible to rotate the plane of vibration with the vibratory structure. The vibration is then motionless relative to a rotating reference system linked to the vibratory structure. Measuring this force makes it possible to determine the angular rate. When no force opposite to the Coriolis forces is applied, measuring the position of the reference system linked to the mode space, rotating with respect to the vibration, which is itself fixed or partially driven with a known fixed coefficient, gives directly the vibratory structure rotation angle information. This is referred to as gyroscope operating mode (or “Whole Angle (WA) mechanization”), in opposition to the previous operating mode, referred to as gyrometer mode (or “Force to Rebalance (FTR) mechanization”).

Coriolis-effect gyroscope sensors are known, which implement a base to which is attached, by means of a central foot, a silica resonator metallized on its surface. Electrodes are arranged on an electrode holder, facing the metallized wall of the resonator, for both making it vibrate (via the application of electrostatic forces) and detecting the latter (via a detection of the capacitive type).

Coriolis-effect gyroscope sensors of the so-called MEMS (“Micro-Electro-Mechanical System”) type are also known, for example, which implement a base to which is attached a quartz or silicon resonator made insulating on its surface by applying a layer of silicon dioxide SiO₂. Electrodes are arranged on the walls of the resonator and on adjacent surfaces for the silicon version, facing each other, for both making it vibrate (electrostatic forces) and detecting these latter (capacitive detection).

Moreover, gyroscope sensors are also known, which implement a base to which is attached, by means of a central rod, a metal resonator. Piezoelectric elements are placed on and against the wall of the metal resonator so as to both making it vibrate and detect these latter by indirect or direct piezoelectric effect.

Finally, vibrating beam accelerometer (VBA) sensors are known, for example, which use a preferentially differential mechanical architecture with a structure made with a MEMS technology, either in quartz, or better in silicon, to benefit from the high accuracy and low cost of production of the etching techniques of the DRIE (Deep reactive-ion etching) type. The operating principle of these accelerometers is based on measuring variations in the resonance frequency of vibrating beams to which is attached a seismic mass with, in response to an external acceleration, one beam in tension and the other in compression. This differential approach makes it possible to compensate for the temperature variations and other environmental disturbances, thus improving the measurement accuracy and stability. The frequency variations are converted into electric signals that can be easily digitized.

These different known vibratory mechanical resonator sensors are wholly satisfactory, but they do have certain drawbacks.

In particular, the resonator of the above-mentioned vibratory gyroscopic sensors is generally made from materials with specific mechanical characteristics that are essential for achieving performance, in particular in terms of damping, which must be the smallest possible. Now, this damping is disturbed by the electromagnetic force resulting from the interaction between the external magnetic field and the current induced at the surface of the resonator when the primary and secondary resonance modes thereof are sustained, whether the resonator is intrinsically metallic, or whether it is made from an insulating material (e.g. silica), or made insulating on its surface (silicon), and coated with conductive electrodes. The metallic resonators made of a ferromagnetic material (such as iron, nickel and cobalt) have, for example, generally, a magnetization that generates a magnetic field that is added to the overall magnetic field passing through the conductive surfaces of the moving resonator, which adds to the electromagnetic force mentioned hereinabove an additional cause disturbing the damping of the resonator vibration. This additional internal field also disturbs the operation of any component sensitive to the magnetic fields and placed in the close vicinity of the metallic resonator. In these latter cases, non-magnetic or diamagnetic materials (e.g. copper alloys) and paramagnetic materials (e.g. aluminum) are known to be used alternately, but this does not eliminate the presence of the disruptive electromagnetic force. Therefore, these known vibratory gyroscopic sensors are likely to interact unintentionally with any external magnetic field, which significantly degrades the performance thereof, in particular when they are low-frequency electromagnetic fields (less than 1 MHz).

The drawbacks described above apply equally to vibrating accelerometers, since the vibrating beams they contain are necessarily coated with electrodes, moved at the frequency of resonance of these beams, and when the sensor passes through an external magnetic field, a disruptive electromagnetic force is created, resulting from the interactions of this external magnetic field with the electrodes moving in this field. The apparent damping and stiffness characteristics of these beams are then disturbed, which causes a significant degradation of their performance.

This is why, in order to maintain the measurement performance of these vibratory mechanical resonator sensors, it is known to surround them with a magnetic shielding cage. It is known to form such a shield using a metal sheet of significant thickness (e.g. 0.5 mm), made of a material having a high magnetic permeability, as for example the nickel-iron alloy called Permalloy®, or also the so-called alloy Mu-metal®.

However, if such known shields allow protecting the known vibratory mechanical resonator inertial sensor from external magnetic influences, they however suffer from serious drawbacks. First, these known shields are indeed ill-suited to the small-size sensors, because the ratio of the shielding surface to the total surface decreases (including the folding zones and free spaces in these zones). These shields are also particularly expensive. They also contribute very significantly to increasing both the size and weight of the vibratory mechanical resonator inertial sensor once shielded, because they are thick enough to provide effective shielding. The performance of these known shields can further be sensitive to the temperature (magnetic misalignment), so that they are not suitable for certain applications involving for example to subject the vibratory mechanical resonator inertial sensor to high temperatures. Moreover, the magnetic shielding properties of the metal sheets conventionally used to form the magnetic shielding cage deteriorate when they are subjected to forming and assembly operations (bending, deformation, welding, machining, etc.). required to form the cage, which limits the possibility to implement performing magnetic shields in certain configurations and/or requires additional cage processing steps (e.g. annealing), which complicate the manufacturing and make it more expensive.

However, as regards in particular Permalloy®, less conventional approaches than machining or sheet forming could be contemplated, as for example the use of a deposit of a thin layer of Permalloy®, by direct current (DC) magnetron cathodic sputtering, where ionized gas molecules bombard a target material, therefore releasing vaporized metal atoms in a plasma that end up physically covering the surface of the substrate. This process is inexpensive and can be carried out in series, but the sputtering speed is extremely slow, of the order of 1 nm/min, and the substrate is exposed to potentially high temperatures. Therefore, this method has mainly been explored for making thin shields that do not allow achieving an optimum level of performance for the vibratory mechanical resonator inertial sensors. Other methods have also been contemplated for making Permalloy® shields, such as laser powder bed fusion (LPBF), also known as direct laser sintering of metal or selective laser fusion. This method, although useful for shielding objects of complex shape, is however particularly expensive and slow, and here again with exposure of the substrate to high temperatures.

The objects assigned to the invention therefore aim to remedy the different drawbacks exposed hereinabove, and to propose a new method for manufacturing a vibratory mechanical inertial sensor that makes it possible to obtain, in a quick, easy and inexpensive way, a vibratory mechanical inertial sensor that, while being particularly lightweight and space-saving, has a design which, irrespective of its size, enables it to maintain its level of measurement performance even when subjected to strong external magnetic fields, particularly at low frequencies.

Another object of the invention aims to propose a new method for manufacturing a vibratory mechanical inertial sensor whose magnetic sensitivity is particularly reduced over a relatively wide-range frequency spectrum.

Another object of the invention aims to propose a new method for manufacturing a vibratory mechanical inertial sensor that, while enabling the sensor's measurement performance to be optimized whatever the environment thereof, does not require an annealing step.

Another object of the invention aims to propose a new method for manufacturing a vibratory mechanical inertial sensor that lends itself particularly well to industrial implementation.

Another object of the invention aims to propose a new method for manufacturing a vibratory mechanical inertial sensor that provides an excellent compromise between measurement accuracy and sensitivity to external magnetic fields.

Another object of the invention aims to propose a new method for manufacturing a vibratory mechanical inertial sensor that makes it possible to obtain, in a quick, easy way, a vibratory mechanical inertial sensor of particularly robust and durable design.

Another object of the invention aims to propose a new vibratory mechanical inertial sensor that has excellent measurement performances, even when subjected to strong external magnetic fields, in particular at low frequencies, while being particularly lightweight, compact and inexpensive to manufacture.

Another object of the invention aims to propose a new inertial unit having a reduced magnetic sensitivity while being particularly lightweight, robust and compact.

The objects assigned to the invention are achieved using a method for manufacturing a vibratory mechanical inertial sensor comprising a step of associating a test body to a base, said test body being designed to vibrate and/or deform and/or move, said method further comprising a step of assembling a cover to said base so that said cover covers the test body and forms with the base a casing within which said test body is housed, a step of vacuuming said casing or filling said casing with a dry gas, and a step of magnetically shielding said casing, which includes a first operation of depositing, by galvanoplasty, a first layer of a first ferromagnetic material on part at least of said casing.

The objects assigned to the invention are also achieved using a vibratory mechanical inertial sensor that can be manufactured by the method according to the invention, said vibratory mechanical inertial sensor comprising at least a base, a test body attached to said base and designed to vibrate and/or deform and/or move, as well as a cover that covers said test body and forms with the base a casing that delimits an inner space within which said test body is housed, said inner space being vacuumed or filled with a dry gas, said casing being at least partly coated with a first layer of a first ferromagnetic material deposited by galvanoplasty, to form a magnetic shield of said casing.

The objects assigned to the invention are also achieved using an inertial unit including at least a plate as well as at least one vibratory mechanical inertial sensor according to the invention, said plate being provided with at least one support to which is attached said vibratory mechanical inertial sensor to be immobilized with respect to said plate, said inertial unit further including a cover that covers said vibratory mechanical inertial sensor and is attached to the plate to form with the latter an enclosure within which said vibratory mechanical inertial sensor is housed, said enclosure being at least partly coated with a secondary layer of said first ferromagnetic material deposited by galvanoplasty.

Other features and advantages of the invention will appear in more detail upon reading of the following description, with reference to the appended drawings, given by way of purely illustrative and non-limiting examples, in which:

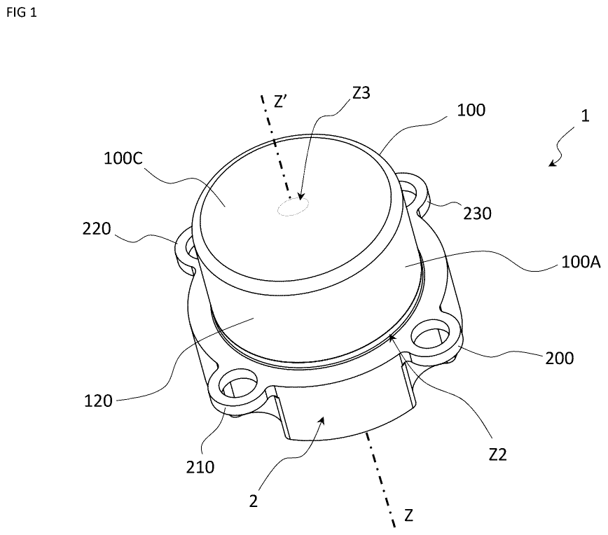

FIG. 1 shows, in a schematic perspective view from above, a first embodiment of a vibratory mechanical inertial sensor according to the invention, which is here a vibratory gyroscopic sensor of the CRG (cylindrical resonator gyroscope) type.

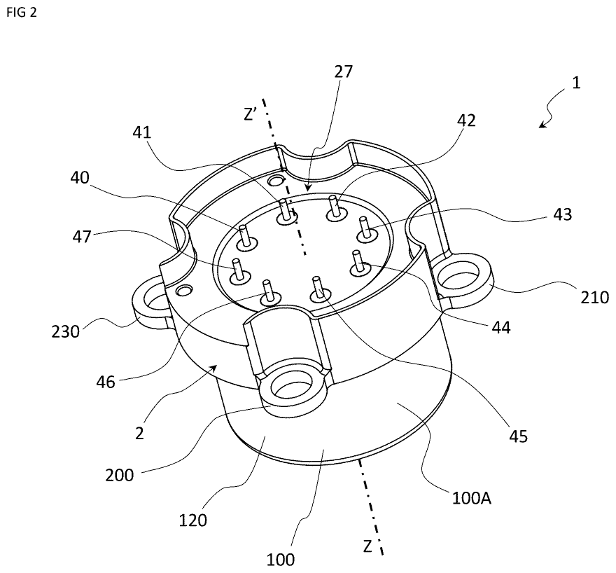

FIG. 2 shows, in a schematic perspective view from below, the vibratory gyroscopic sensor of FIG. 1.

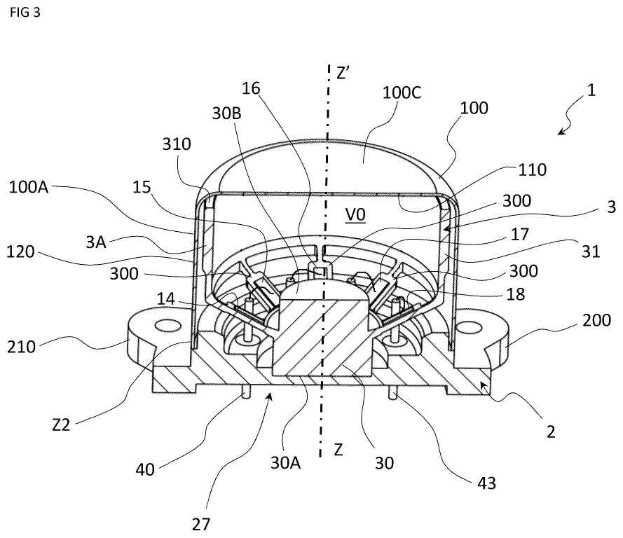

FIG. 3 shows, in a cut schematic perspective view, the vibratory gyroscopic sensor of FIGS. 1 and 2.

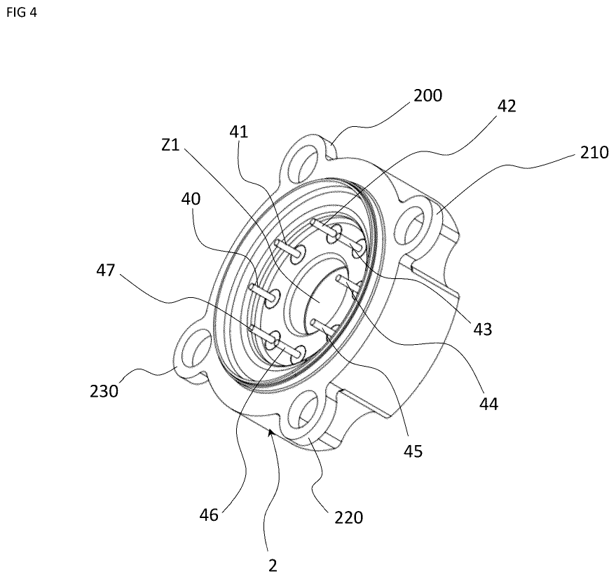

FIG. 4 shows, in a schematic perspective view from above, a design detail of the vibratory gyroscopic sensor of FIGS. 1 to 3, here corresponding to the base thereof.

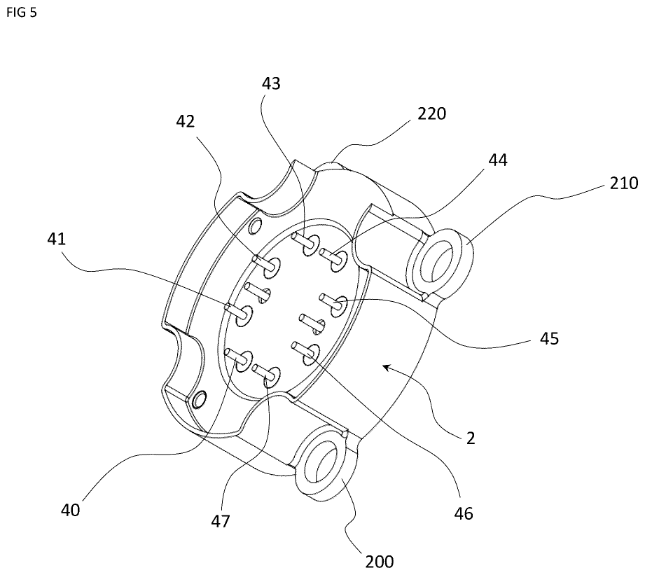

FIG. 5 shows, in a schematic perspective view from below, the base of FIG. 4.

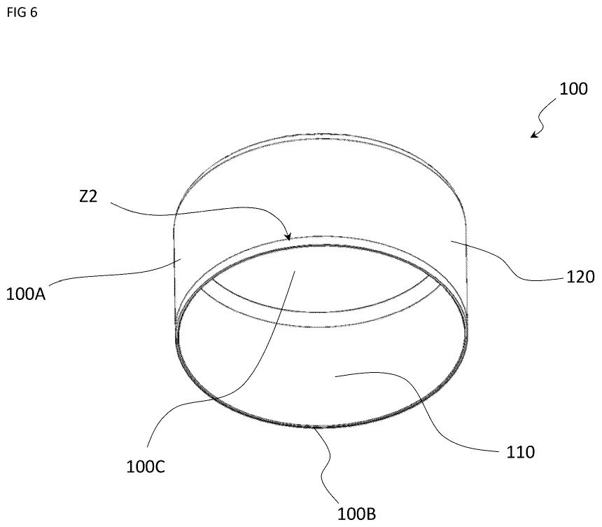

FIG. 6 shows, in a schematic perspective view from below, a design detail of the vibratory gyroscopic sensor of FIGS. 1 to 3, here corresponding to the cover thereof.

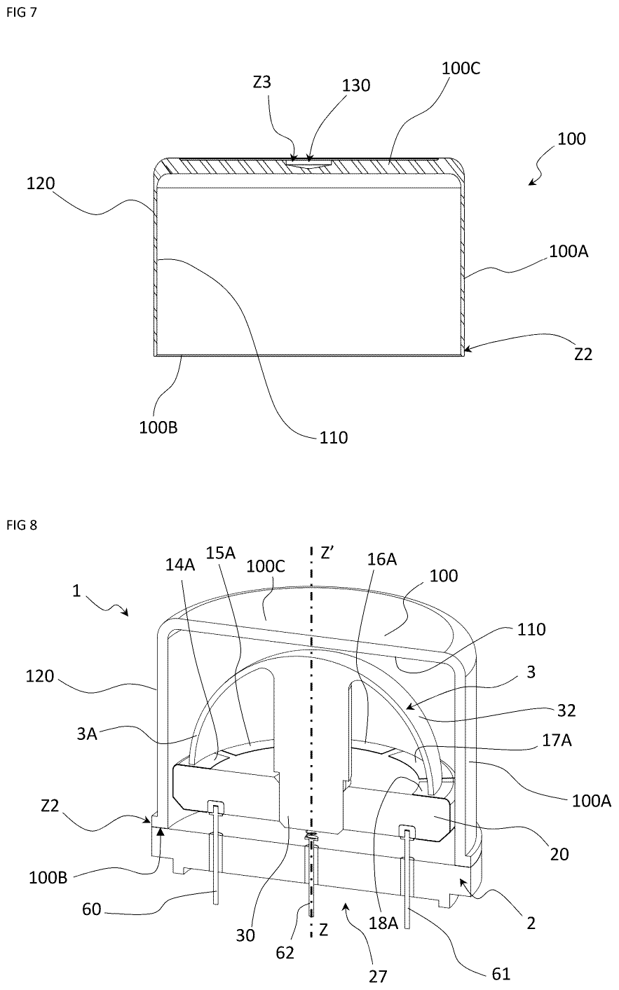

FIG. 7 shows, in a cut schematic view, the cover of FIG. 6.

FIG. 8 shows, in a cut schematic perspective view, a second embodiment of a vibratory mechanical inertial sensor according to the invention, which is here a vibratory gyroscopic sensor of the HRG (“Hemispherical Resonator Gyroscope”) type.

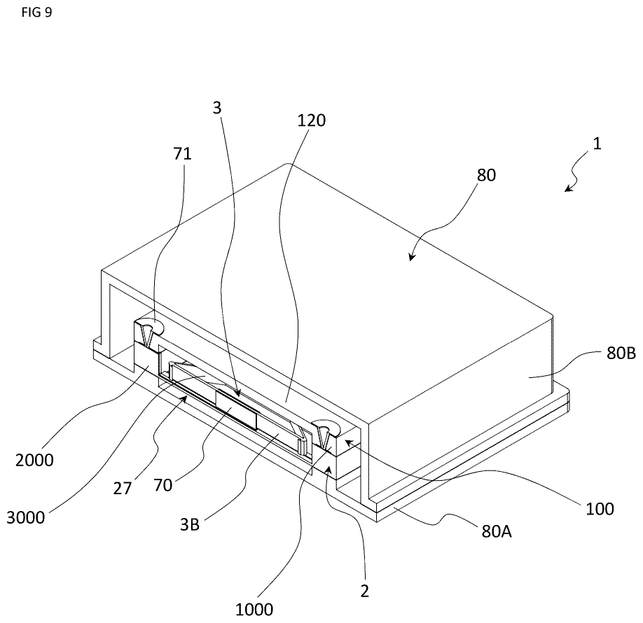

FIG. 9 shows, in a schematic perspective view, a third embodiment of a vibratory mechanical inertial sensor according to the invention, which is here a vibrating beam accelerometer (VBA) of the MEMS (“Micro-Electro-Mechanical System”) type.

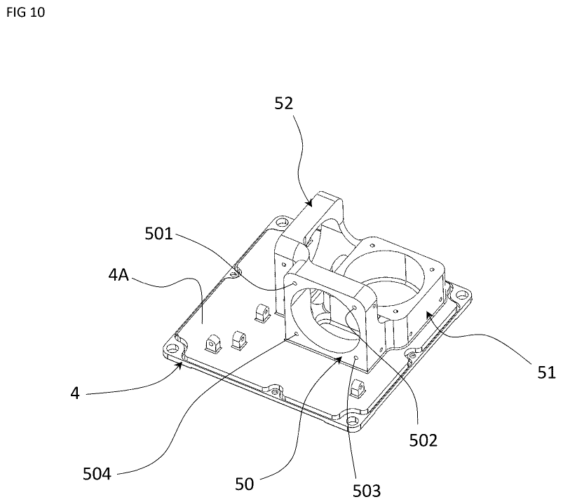

FIG. 10 shows, in a schematic perspective view from above, a design detail of an inertial unit according to the invention, corresponding to a plate on which three gyroscopic sensors in accordance with the invention and/or three accelerometers in accordance with the invention are to be mounted, along the three directions of space, respectively.

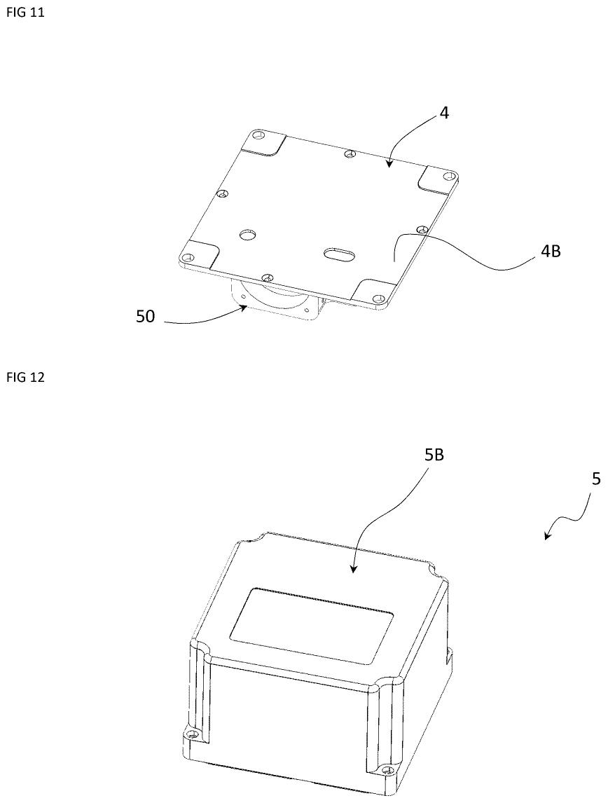

FIG. 11 shows, in a schematic perspective view from below, of the plate of FIG. 10.

FIG. 12 shows, in a schematic perspective view from above, a design detail of an embodiment of the inertial unit according to the invention, corresponding to a cover intended to cover the plate and the inertial sensors carried by the latter.

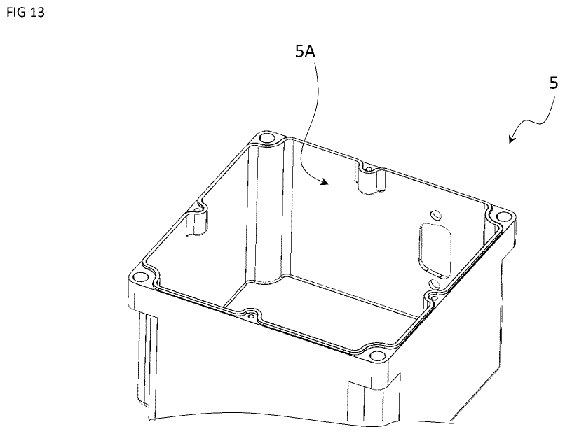

FIG. 13 shows, in a schematic perspective view from below, the cover of FIG. 12.

The invention relates to a method for manufacturing a vibratory mechanical inertial sensor 1, as well as a vibratory mechanical inertial sensor 1 that can be manufactured by said method. Said vibratory mechanical inertial sensor 1 according to the invention is preferably obtained using the manufacturing method according to the invention, whereas the manufacturing method according to the invention is preferentially a method for manufacturing the vibratory mechanical inertial sensor 1 according to the invention. However, it is perfectly conceivable, for example, that the vibratory mechanical inertial sensor 1 according to the invention can be obtained by another manufacturing method than the method of the invention, and conversely, that the manufacturing method according to the invention can allow obtaining a vibratory mechanical inertial sensor that is different from the vibratory mechanical inertial sensor 1 according to the invention. For the sake of brevity, the following description will both relate to said method according to the invention and said vibratory mechanical inertial sensor 1 according to the invention, which means that the elements of the following description that relate to said manufacturing method apply, mutatis mutandis, to said vibratory mechanical inertial sensor 1, and reciprocally, that the elements of the following description that relate to said vibratory mechanical inertial sensor 1 apply, mutatis mutandis, to said manufacturing method.

The manufacturing method according to the invention comprises a step of associating a test body 3 with a base 2. Said test body 3 is designed to vibrate and/or deform and/or move, for example globally or locally, so that the vibration and/or deformation and/or movement possibilities thereof can be exploited to determine for example characteristics of a movement and/or a direction. Said base 2 is, for example, metallic (as in the embodiments of FIGS. 1 to 8) or made of glass or silica (as in the embodiment of FIG. 9), and preferably provides in particular a support function. Base 2 thus forms, for example, a pedestal for test body 3 that is attached thereto. Base 2 is for example provided, as illustrated in FIGS. 1 to 5, with fastening means 200, 210, 220, 230, that are for example in the form of a plurality of fastening lugs, each including a through-hole to enable the inertial sensor 1 to by screwed to a frame, for example to a plate 4 of an inertial unit or any other equipment.

In accordance with the embodiments of FIGS. 1 to 8, said mechanical inertial sensor 1 is for example a vibratory gyroscopic sensor, preferably a Coriolis-effect asymmetrical one, i.e. a vibratory sensor based on the Coriolis forces. Said vibratory gyroscopic sensor is therefore a vibratory inertial sensor of the CVG (“Coriolis Vibratory Gyroscope”) type. It advantageously forms in this case a sensor designed (i) to measure a rotation angle (gyroscope operation, also called WA mode as mentioned hereinabove), in which case it is a vibratory gyroscope and/or (ii) to measure a rotational speed (gyrometer operation, also called FTR mode as mentioned hereinabove), in which case it is a vibratory gyrometer, it being understood that said gyrometer can also determine an angle by integrating the angular speed.

The invention is not limited to a specific type of vibratory gyroscopic sensor. The latter can for example form a cylindrical resonator gyroscopic sensor (or CRG, «Cylindrical Resonator Gyroscope») as in the embodiment of FIGS. 1 to 7, or a hemispherical resonator gyroscopic sensor (or HRG, Hemispherical Resonator Gyroscope») as in the embodiment of FIG. 8, or also, for example, a MEMS gyroscopic sensor whose resonator takes the form of a ring generally made of silicon, or whose resonator is consisted of four oscillating masses forming two pairs vibrating at the same frequency but in phase opposition (in this case, we talk about a “double planar tuning fork”).

The invention is moreover not limited to a vibratory mechanical inertial sensor that forms a vibratory gyroscopic sensor. Therefore, the vibratory mechanical inertial sensor 1 is for example a vibrating beam accelerometer, and in particular a VBA accelerometer of the capacitive silicon or quartz MEMS (“Micro-Electro-Mechanical System”) type, as in the embodiment of FIG. 9.

In the embodiments of FIGS. 1 to 8, test body 3 is formed by a resonator 3A, that is intended to vibrate in response to an excitation. Said resonator 3A has for example at least one 2nd-order resonance mode divided into a primary mode and a secondary mode that are modally orthogonal to each other, with for example elliptic deformations (case of a resonator 3A having a shape of revolution, as illustrated in the figures), and in principle of same frequencies.

Resonator 3A advantageously includes, as illustrated in FIGS. 3 and 8, a central foot 30 by which resonator 3A is attached, directly (FIG. 3) or indirectly (FIG. 8), to said base 2, for example in a fastening zone Z1 of the latter for the embodiment of FIGS. 3 and 4. Advantageously, said central foot 30 has a massive and monolithic nature, i.e. it is formed by a one-piece, monobloc part, preferably made of metal or silica or silicon. In the embodiments of FIGS. 3 and 8, said step of associating test body 3 to base 2 includes an operation of fastening resonator 3A to base 2 by fastening central foot 30, e.g. by welding, brazing or bonding, either directly to base 2, at the fastening zone Z1 (case of FIG. 3), or at an intermediate plate 20 (embodiment of FIG. 8) that is for example metallic or made of glass or ceramic. Said intermediate plate 20 is itself advantageously connected to base 2, for example on stilts, by means of electrically conductive rods 60, 61 (and six others that are not shown but can be deduced from the previous ones by symmetry). Vibratory gyroscopic sensor 1 according to FIGS. 1 to 8 thus advantageously comprises mechanical link means that provide a direct or indirect connection of central foot 30 to base 2, in order to preferably establish an embedded connection between central foot 30 and base 2, to immobilize central foot 30 relative to base 2. Preferably, foot 30 has substantially a shape of revolution about a central axis Z-Z′ that corresponds for example to the sensitive axis along which the vibratory gyroscopic sensor of each FIGS. 3 and 8 is designed to measure an angular speed and/or an angular movement. In the embodiment of FIGS. 1 to 7, foot 30 extends for example, along said central axis Z-Z′, between an outer face 30A, which is preferably planar and is for example received in a housing formed in base 2 and that forms the fastening zone Z1 and a free inner face 30B, which is preferably also planar.

In the embodiment of FIGS. 1 to 7, resonator 3A comprises a vibrating cylinder 31, which is preferably attached to said foot 30, the latter advantageously carrying vibrating cylinder 31. Vibrating cylinder 31 advantageously has a shape of revolution, about said central axis Z-Z′. It rises for example between a lower edge connected to foot 30, for example by arms 300, and a free upper edge 310 that delimits an opening giving access to an internal volume VO. Vibrating cylinder 31 thus forms a side wall that surrounds the internal volume VO. Each arm 300 is for example formed by a stiff tab, which extends radially with respect to the central axis Z-Z′, about and from foot 30, to connect the latter to vibratory cylinder 31. As illustrated in the figures, vibrating cylinder 31 advantageously has the general shape of a straight cylinder, which preferentially extends between a lower circular edge connected to foot 30 and a free upper circular edge. Advantageously, central foot 30 and vibratory cylinder 31 form a single and same one-piece part and are preferably formed of a same material. In other words, foot 30 and side wall 31 form a single one-piece part, which is preferably fully metallic. Advantageously, vibrating cylinder 31 is made of martensitic steel, e.g. X30Cr13 steel or maraging steel. The use of either one of the above-mentioned steels is particularly advantageous because the steels in question have excellent mechanical damping properties, which makes it possible to obtain a high quality factor (Q), guaranteeing an excellent level of measurement performance from vibrating gyroscopic sensor 1.

In the embodiment of FIG. 8, resonator 3A advantageously comprises a vibrating hemispherical shell 32 connected to foot 30 at the center thereof, said shell 31 being preferably made of quartz, or sapphire, or silica glass, preferentially metallized on its surface, and advantageously forms a one-piece part with foot 30.

Advantageously, in the embodiments of FIGS. 1 to 8, the method comprises a step of associating at least one excitation device to said resonator 3A, to vibrate it, and more precisely to vibrate the vibrating cylinder 31 (FIG. 3) or the vibrating hemispherical shell 32 (FIG. 8), and in particular said symmetrical primary and secondary modes of vibration of the resonator 3A. Advantageously, the method also comprises a step of associating at least one detection device with said resonator 3A, to detect vibrations of said resonator 3, and in particular the vibrations of the vibrating cylinder 31 or of the vibrating hemispherical shell 32 excited by said at least one excitation device attached to said resonator 3A. Said excitation and detection devices can be of similar or different natures, and be based, for example, on an excitation principle of electrostatic, electromagnetic and/or piezoelectric nature, and a detection principle of electrostatic, optical, electromagnetic and/or piezoelectric nature, respectively, without this list being limitative.

Preferably, as in the case of FIGS. 1 to 7, the vibratory gyroscopic sensor that advantageously forms the inertial sensor 1 comprises piezoelectric elements 14, 15, 16, 17, 18 (and three others that are not shown but can be deduced from the previous ones by symmetry), which form both said excitation devices and said detection devices. Each of said piezoelectric elements is thus designed in order, on the one hand, to impart vibrations to the vibrating cylinder 31 (FIG. 3), so as to excite in particular the symmetrical primary and secondary modes of resonance, and on the other hand, to detect the vibrations of said vibrating cylinder 31. The piezoelectric elements 14, 15, 16, 17, 18 (and three others that are not shown but can be deduced from the previous ones by symmetry) also provide a dual function, vibratory excitation on the one hand and/or vibratory detection on the other hand, with a multitude of possible sub-variants using a variable number of piezoelectric elements for detection and excitation. In the embodiment illustrated in FIGS. 1 to 7, said steps of associating the excitation and detection devices include for example an operation of fastening the piezoelectric elements 14, 15, 16, 17, 18 (and three others that are not shown but can be deduced from the previous ones by symmetry) on each of the arms 300, respectively, which provide the link between foot 30 on the one hand and vibrating cylinder 31 on the other hand. The piezoelectric elements 14, 15, 16, 17, 18 (and three others that are not shown but can be deduced from the previous ones by symmetry) are for example fastened by bonding or by brazing on the upper surface of each of said arms 300, which enables some of them to impart vibrations to said arms 300, so that these latter communicate in turn the vibrations in question to the vibrating cylinder 31 to which they are attached. Conversely, the vibrations of said cylinder 31 are transmitted to each of the arms 300 and thus detected by certain of the piezoelectric elements 14, 15, 16, 17, 18 (and three others that are not shown but can be deduced from the previous ones by symmetry) fastened to said arms 300.

Preferably, in the case of FIG. 8, the vibratory gyroscopic sensor that advantageously forms the inertial sensor 1 comprises electrodes 14A, 15A, 16A, 17A, 18A (and three others that are not shown but can be deduced from the previous ones by symmetry), arranged on the surface of the intermediate plate 20, facing the resonator 3A, which form both said excitation devices and said detection devices, in combination with the electrode deposited on the adjacent surface of resonator 3A and that is connected by one or more conductive deposits, generally of same nature as the adjacent electrode on the resonator, running along the walls of resonator 3A, then along foot 30, towards an electrical contact obtained by an elastic electrical link with an electrically conductive rod 62, generally collinear to the symmetry axis Z-Z′, and passing through base 2 in the same way as rods 60, 61 (and six others that are not shown but can be deduced from the previous ones by symmetry). Each of said electrodes is therefore designed so as, on the one hand, to impart vibrations to the vibrating hemispherical shell 32 (FIG. 8), in order to excite in particular the symmetrical primary and secondary modes of resonance, and on the other hand, to detect the vibrations of said vibrating hemispherical shell 32. The electrodes 14A, 15A, 16A, 17A, 18A (and three others that are not shown but can be deduced from the previous ones by symmetry) thus provide a dual function, vibratory excitation on the one hand and/or vibratory detection on the other hand. In the embodiment illustrated in FIG. 8, said steps of associating the excitation and detection devices include for example an operation of depositing the electrodes 14A, 15A, 16A, 17A, 18A (and three others that are not shown but can be deduced from the previous ones by symmetry), respectively, on the intermediate plate 20 that provides the link between foot 30 on the one hand and vibrating hemispherical shell 32 on the other hand. The electrodes 14A, 15A, 16A, 17A, 18A (and three others that are not shown but can be deduced from the previous ones by symmetry) are for example deposited by a physical vapor deposition (PVD) method, and impart vibrations to the vibrating hemispherical shell 32 under the effect of electrostatic forces as soon as a difference of potential appears between these electrodes and the metallization opposite resonator 3A. Conversely, the vibrations of said vibrating hemispherical shell 32 are detected by modulation of the capacitance between said electrodes and the metallization of the resonator, resulting from the modulation of the air gap between the vibrating hemispherical shell 32 and the intermediate plate 20 carrying these electrodes.

In the particular embodiment of FIG. 9, in which inertial sensor 1 is a vibrating accelerometer (VBA) of the MEMS (“Micro-Electro-Mechanical System”) type, test body 3 is formed by a test mass that is for example made by micro-machining a silicon wafer 3B. The micro-machining in question is for example made by a DRIE («Deep Reactive Ion Etching») method that makes it possible to cut in silicon wafer 3B an element forming a test mass supported by elastic arms 3000 (visible in FIG. 9), these arms being themselves connected to the two ends of a thin beam of this same wafer, and anchored to the rest of silicon wafer 3B. The test mass on these elastic arms forms a mass-spring system, causing, in the presence of an acceleration in the plane of silicon wafer 3B, a compression or stretching of the beam, leading to a change in the frequency of the beam. A system with two beams operating in phase opposition, one being compressed, and the other being simultaneously stretched, advantageously offers the advantage of a differential effect which eliminates common mode errors and sensitivities (FIG. 9). The measurement of the difference of frequency of the two beams is proportional to the external acceleration applied to the test mass. Each beam is advantageously provided in surface with one or more electrically conductive electrodes, providing detection functions, preferably arranged on the vibration bellies of said beam, with, opposite thereto, one or more immobile electrodes 70 attached with a fixed part of the silicon wafer. The detection electrodes measure the modulation of the air gap between the vibrating beam and the fixed electrode 70, via the modulation of capacitance between these electrodes, to deduce therefrom by external electronic means, the frequency of this modulation carrying the acceleration information. In this particular embodiment, base 2 is preferably formed by a first support part 2000, made of glass or silicon, which advantageously has an concave inner side intended to come opposite silicon wafer 3B. Preferably, silicon wafer 3B, that carries the test mass forming test body 3, is attached by thermocompression to said first support part 2000 on opposite metallized surfaces, said first support part 2000 advantageously forming base 2.

Advantageously, the method comprises a step of providing electronic processing and control means, which include for example an electronic board (not shown), during which said electronic processing and control means (electronic board) are housed at least partly into base 2, or against the latter, or also near the latter.

In the embodiments of FIGS. 1 to 8, said electronic processing and control means are arranged in a housing 27 formed at the external surface of base 2, on the side opposite to that on which rises the resonator 3A (FIGS. 3 and 8). Base 2 also advantageously extends, in the embodiments of FIGS. 1 to 8, between the electronic board on the one hand and the resonator 3A on the other hand.

In embodiments of FIGS. 1 to 7, in order to electrically connect to the above-mentioned electronic board the piezoelectric elements 14, 15, 16, 17, 18 (and three others that are not shown but can be deduced from the previous ones by symmetry), which preferentially form the excitation and detection devices, the manufacturing method advantageously comprises a step of associating electrically conductive (metal) rods 40, 41, 42, 43, 44, 45, 46, 47 to base 2, by inserting said rods 40, 41, 42, 43, 44, 45, 46, 47 into through-orifices in said base 2 so that said rods project from either side of base 2, as illustrated in the figures. Said rods 40, 41, 42, 43, 44, 45, 46, 47 are intended to be electrically connected to said excitation and/or detection devices, i.e. for example (as in the embodiment of FIGS. 1 to 7) to said piezoelectric elements 14, 15, 16, 17, 18 (and three others that are not shown but can be deduced from the previous ones by symmetry), preferably by means of micro-cables (visible in FIG. 3). Each conductive rod 40, 41, 42, 43, 44, 45, 46, 47 advantageously has a substantially stiff nature, whereas the micro-cables have a soft and flexible nature, and are for example made of metal (preferably, aluminum or gold). More precisely, each conductive rod 41, 42, 43, 44, 45, 46, 47 preferably extends between a lower end, which is intended to be electrically connected to the electronic board arranged in housing 27, and an upper end at which is for example attached the micro-cable that connects the relevant conductive rod to one of the above-mentioned piezoelectric elements 14, 15, 16, 17, 18 (and three others that are not shown but can be deduced from the previous ones by symmetry). The conductive rods 40, 41, 42, 43, 44, 45, 46, 47 advantageously each pass through a support wall of base 2, through passages formed through said support wall and that are fitted with insulating bushings (e.g. made of glass, preferably with a coefficient of thermal expansion adapted to that of the base 2) locally forming an electrically insulating sheath which surrounds each conductive rod to avoid it to enter in contact with said support wall, which is for example metallic. The conductive layers 40, 41, 42, 43, 44, 45, 46, 47 thus pass through base 2 up to arriving into housing 27, where they are electrically connected to the above-mentioned electronic board (not shown in FIG. 3).

In the embodiments of FIG. 8, in order to electrically connect to the electronic board the electrodes 14A, 15A, 16A, 17A, 18A (and three others that are not shown but can be deduced from the previous ones by symmetry), which preferentially form the excitation and detection devices, the manufacture method advantageously comprises a step of associating to the base 2 electrically conductive rods (metallic) 60, 61 (for example, 8 in number, arranged symmetrically about the axis Z-Z′), as well as for example a central rod 62 advantageously aligned with the axis of foot 30 and enabling the routing of a high electric voltage towards the metallization of the resonator 3A, by inserting said rods in through-orifices in said base 2 so that said rods project from either side of base 2, as illustrated in FIG. 8. Said rods are intended to be electrically connected to said excitation and/or detection devices, i.e. for example, as in the embodiment of FIG. 8, to the electrodes 14A, 15A, 16A, 17A, 18A (and three others that are not shown but can be deduced from the previous ones by symmetry), preferably by means of welds (visible in FIG. 8). Each conductive rod 60, 61 advantageously has a substantially stiff nature. More precisely, each conductive rod 60, 61 extends preferably between a lower end, which is intended to be electrically connected to the electronic board arranged in housing 27, and an upper end at which is made the welding to intermediate plate 20. Conductive rods 60, 61 each advantageously pass through a support wall of base 2, through passages formed through said support wall and that are that are fitted with insulating bushings (e.g. made of glass) locally forming an electrically insulating sheath which surrounds each conductive rod to avoid it to enter in contact with said support wall, which is for example metallic. Conductive rods 60, 61 thus pass through base 2 up to arriving into housing 27, where they are electrically connected to the above-mentioned electronic board (not shown in FIG. 8).

As illustrated in the figures, the method moreover comprises a step of assembling a cover 100 to said base 2, so that said cover 100 covers said test body 3 and forms with base 2 a casing within which said test body 3 is housed. The sub-unit formed by this casing and the test body 3 housed therein generally referred to as “sensitive element” and forms the electromechanical part of inertial sensor 1, which moreover requires known electronic means (not shown) for the implementation thereof and that have been mentioned hereinabove. The name “casing” can be indifferently used to denote the casing in the assembled state, i.e. resulting from said step of assembling said cover 100 to said base 2, or the casing in the non-assembled state, in which cover 100 and base 2 are still separated from each other. Said cover 100 is for example made of a metallic material (FIGS. 1 to 8) or glass or silicon (FIG. 9), and is advantageously intended to cooperate with base 2 to delimit with the latter a closed inner space that receives the sensitive mechanic structure (test body 3 described hereinabove) of inertial sensor 1, in order to isolate and protect it from the outer environment. The housing so formed by base 2 and cover 100 is advantageously gas tight, thanks to the implementation of suitable sealing means arranged at the interface between cover 100 and base 2, which makes it possible to control the atmosphere inside the housing in question.

For example, as in the embodiments of FIGS. 1 to 8, cover 100 is bell-shaped, with a cylindrical side wall 100A having a free edge 100B, as well as a bottom wall 100 from and at the periphery of which said cylindrical side wall 100A extends. Cover 100 thus has the shape of a cap, or container, which together with base 2 forms an enclosure, preferably hermetically sealed, within which test body 3 is housed. Cover 10 thus advantageously has an inner face 110 intended to face the inside of the casing and an opposite, outer face 120. Advantageously, said step of assembling cover 100 to base 2 includes a docking operation so that free edge 100B comes into contact with said base 2, along an interface of contact that is for example continuous, and preferably circular. Said step of assembling cover 100 to base 2 also includes, after said docking operation, a welding or brazing operation to make a welding or brazing bead, preferably substantially continuous, linking base 2 to an end zone Z2 of cylindrical side wall 100A located near free edge 100B, on the outer face 120 of cover 100. For example, as illustrated in FIGS. 1 to 8, said end zone Z2 forms a circumferential strip that extends, from free edge 100B, over a fraction (e.g. at most 10%, more preferentially at most 5%, and particularly preferentially at most 3%) of the height of cylindrical side wall 100A (measured parallel to the central axis Z-Z′). Said welding or brazing operation is thus carried out so that the welding bead adheres both to said end zone Z2 and to a circumferential zone of base 2, which is adjacent to said end zone Z2, to attach cover 100 to base 2, while preferably forming a hermetic seal at the interface between cover 100 and base 2.

In the embodiment of FIG. 9 (inertial sensor 1 forming a MEMS vibrating accelerometer (VBA)), cover 100 is advantageously formed by a second support part 1000 made of glass or silicon, which advantageously has a concave inner face intended to face the silicon wafer 3B in which is arranged the test mass forming test body 3. Preferably, silicon wafer 3B, which carries the test mass forming test body 3, is bonded by thermocompression, using metallized surfaces, with or without the addition of brazing metal, to said second support part 1000 that advantageously forms cover 100. In the particular embodiment of FIG. 9, said cover 100 and base 2 are thus formed by the first support part 2000 and the second support part 1000, respectively, both made of glass or silicon. Silicon wafer 3B, which carries the test mass forming test body 3, is advantageously interposed between said first and second support parts 2000, 1000 and attached to these latter by thermocompression at the periphery, in order to form a closed casing (preferably, hermetic) delimiting a cavity that receives the test mass carried by silicon wafer 3B. In accordance with the embodiment of FIG. 9, each inner electrode, as for example the electrically conductive electrode 70, is advantageously connected to at least one metallized electrical connection well 71 formed in the second support part 1000, here forming cover 100. Preferably, within the framework of the embodiment of FIG. 9, the method comprises a step of encapsulating the casing here formed by the first and second support parts 2000, 1000 in an outer envelope 80, formed for example by a support 80A, to which is fastened the casing and a cover 80B attached to support 80A to cover the casing, as illustrated in FIG. 9. Said support 80A and cover 80B are for example made of a metallic material or ceramic material. In this embodiment, housing 27 receiving the electronic board can be inside the outer envelope 80, or possibly outside the latter. In the embodiment of FIG. 9, the electronics associated with housing 27 is for example inside the outer envelope 80 and can advantageously be an ASIC (Application-Specific Integrated Circuit). The electronics can communicate with complementary electronic elements placed outside of the outer envelope 80, via an interconnection via a connector (not shown in FIG. 9) passing through the outer envelope 80. It is to be noted that each well 71 can also similarly be made in the first support part 2000, with creation of an air gap between the first support part 2000 and the support 80A, for example by means of added extensions or by design, to prevent these wells short-circuiting with support 80A.

Advantageously, the manufacturing method comprises a step of vacuuming said casing formed by assembling cover 100 to base 2, in order to place the inside of said housing under vacuum, and for example under a coarse vacuum (pressure between atmospheric pressure and 100 Pa), or under a primary vacuum (atmospheric pressure between 100 Pa and 0.1 Pa), or even under a secondary vacuum (pressure between 0.1 Pa and 10⁻⁶ Pa) or even under ultra-high vacuum (pressure between 10⁻⁶ Pa and 10⁻⁹ Pa) or even possibly under ultra-ultra-high vacuum (pressure less than 10⁻⁹ Pa). As an alternative, said method comprises a step of filling said casing with a dry gas, so that the inside of the casing is filled with dry gas. Said dry gas contains substantially no liquids nor condensates. It is for example formed of nitrogen (N₂), or an inert gas such as argon (Ar). Generally, vacuuming the chamber containing the vibrating test body, or its filling with a dry gas, helps minimizing the external disturbances, improves the stability of the measurements and extends the sensor durability, thanks in particular to the reduction of the damping affecting for example the amplitude and stability of the vibrations in the case where test body 3 includes a resonator (FIGS. 1 to 8) or a vibrating beam (FIG. 9). In the case of the alternative of FIG. 9, filling the inner volume of the casing with a dry gas may be preferably to vacuum to damp the movements of the test mass.

For example, in the embodiment of FIGS. 1 to 7, the vacuuming step is made by means of an air suction tube introduced into the casing, preferably through a suction orifice formed through said bottom wall 100C (in a vacuuming zone Z3) which is then sealed (once the vacuuming operation ended). A vacuuming method similar in principle to the one described hereinabove can be implemented, with the necessary adaptations, for the embodiment shown in FIG. 8, for example using the principle of a metal port passing through the base 2 and vacuum-clamped to obtain the desired tightness. It is called “seal welding” (“queusotage” in French). As regards the embodiment of FIG. 9, the assembly of base 2 to cover 100, both made of glass or silicon, will be advantageously made by vacuum thermocompression.

The manufacturing method according to the invention further comprises a step of magnetically shielding the casing formed by base 2 and cover 100. Said shielding step includes a first operation of depositing, by galvanoplasty (also known as electrodeposition), a first layer of a first ferromagnetic material on part at least of said casing, in order to reduce the sensitivity of the vibratory mechanical inertial sensor 1 to the external magnetic fields, in particular at low frequencies, which could affect the measurement performance. The first operation of depositing said first layer by galvanoplasty thus consists of an operation of electrodeposition of the first layer, which is based on an electroplating technique making it possible to apply a metal deposit (her, said first ferromagnetic material) at the surface of an object (herein at least part of the casing). Said electrodeposition operation (galvanoplasty) is advantageously an electroplating operation, which can possibly be a composite electroplating (or “electro-cladding”) operation.

Galvanoplasty generally consists in depositing uniformly a metal on a conductive surface in a bath of salt (sulfate electrolyte, or citrate electrolyte for greater efficiency, or chloride electrolyte for special applications, etc.) via electric current. More precisely, electrodeposition (galvanoplasty) is based on the following general principle:
the target object to be coated (for example, here the casing, or part of the latter as for example cover 100 and/or base 2) is placed in a bath containing a solution of electrolyte;
the target object forms a cathode connected to the negative terminal of a direct current source, whereas an anode made of the material to be deposited is connected to the positive terminal and also immersed in the bath;
the application of an electric current causes the migration of the metal ions of the anode towards the cathode, where they are deposited and form a uniform layer of metal.

Galvanoplasty makes is possible to obtain high speeds of deposition (which can for example be almost 100 times higher than those implemented by the cathodic sputtering technique mentioned hereinabove).

The implementation of a deposition by such an electrolytic technique makes it possible to form a magnetic shield as close as possible to test body 3, in the form of a magnetic shield layer that can faithfully match the shape of the sensitive element, and more precisely of the casing, thus makes it possible to obtain a particularly efficient magnetic shield, without having to use, as in the prior art, a shielding cage liable to increase the size and weight of the inertial sensor 1, with moreover a risk of degradation of the shielding properties of the cage during its manufacturing by forming and assembling thick metal sheets. The use of a shield formed by a layer of ferromagnetic material directly electrodeposited on at least one part of the surface of the sensitive element, and more precisely of the casing, offers, in addition to the magnetic shield, technical effects and particularly interesting advantages, such as, in particular:
Improvement of the structural integrity and tightness: by electrodepositing a layer of ferromagnetic material directly on the surface of the sensitive element, and more precisely the casing, in particular on the wall of cover 100, the robustness and durability of the sensitive element, and in particular cover 100, are improved. This is a synergistic effect: in addition to providing electromagnetic shielding, the electroplating of the ferromagnetic material layer mechanically reinforces the sensitive element, and more precisely the casing, and in particular cover 100. The implementation of an electroplated layer of magnetic shield further provides an additional sealing barrier, thus improving the integrity of the vacuum inside the sensitive element.
Reduction of the complexity of manufacturing and costs: the use of galvanoplasty to deposit a layer of ferromagnetic material makes the manufacturing process simpler by eliminating the need for manufacturing and assembling distinct shielding cages. This makes it possible to reduce the costs of production and accelerate the assembly process.
Minimizing the footprint: by incorporating the electromagnetic protection directly to the sensible element, herein the casing, the space needed for the external shield is reduced, which is particularly advantageous for the applications in which the space is limited.
Improving the shield efficiency: galvanoplasty makes it possible to deposit a uniform and continuous coating, provided that the part to be coated does not have excessively sharp radii (e.g. less than 0.2 mm—this requirement can be taken into account when designing the sensitive element), thus potentially offering a particularly homogeneous coating, efficient against electromagnetic interferences.
Reducing heat gradients: the temperature differences and the heat gradients in and about said sensitive element, and more precisely of said casing within which test body 3 is housed may cause anisotropies of the physical parameters degrading the vibratory mechanical inertial sensor performance due to non-uniform expansion or contraction of test body 3. A shield coating deposited by galvanoplasty may, in addition to its protective function against electromagnetic interferences, help homogenize the thermal response of the casing, improving the thermal stability of the vibratory mechanical inertial sensor.

Finally, direct deposition of a ferromagnetic shielding material over at least part of the casing (i.e. over at least part of cover 100 and/or base 2) that encloses test body 3 enables in particular to minimize the weight and size with respect to the conventional shielding solutions, to increase robustness and durability, and also a particularly improved and more stable measurement performance. The use of such a galvanic deposition operation directly on the casing further enables a particularly fast and cheap manufacturing method, as said first electroplating operation can also be cleverly integrated into the overall method of manufacturing the sensing element, as will become clear below.

Optionally, the method includes a preliminary operation of surface treatment on the sensitive element, and more precisely of the casing, to be electroplated, before the first operation of galvanic deposition of the first layer. Said preliminary treatment operation includes, for example, depositing a primer layer (e.g. containing copper) on said surface of the casing to be coated. In the case where the wall of the sensitive element, and more precisely of the casing, covered with the first layer of the first ferromagnetic material is metallic, said first layer can be directly deposited by galvanoplasty on the metal wall of the casing (embodiments of FIGS. 1 to 8), without first applying a primer layer. The use of such a primer layer may nevertheless be preferable even in this case, in which the surface to be coated is metallic. In the case where the casing wall to be coated by galvanoplasty is not metallic, and is for example made of glass or silicon, as in the embodiment of FIG. 9, the method preferably includes said preliminary operation of surface treatment on the sensitive element (and more precisely the casing) to be coated by galvanoplasty, before galvanic deposition of the first layer, in the form, for example, of depositing, on said casing surface to be coated, said primer layer (e.g. a nickel-gold alloy containing copper) that bonds to the glass or silicon wall of the casing and on which is then deposited by galvanoplasty the first layer of the first ferromagnetic material.

Advantageously, said first ferromagnetic material of the first layer is a material with a nanocrystalline structure. Said nanocrystalline structure has for example a mean grain size of between 5 and 100 nm, preferably between 5 and 50 nm, more preferentially between 10 and 30 nm. The use of such a nanocrystalline structure makes it possible to provide said first layer with a high magnetic permeability, which offers an excellent magnetic shielding effect, in particular against external low-frequency magnetic fields (e.g. of less than 1 MHz), while providing a wide spectrum shield. This minimizes the thickness of said first layer while maintaining optimum shielding performance. Moreover, the use of a material with a nanocrystalline structure provides said first layer with particularly high hardness and mechanical strength, which makes the first layer particularly robust, reliable and durable.

Advantageously, said first ferromagnetic material of the first layer has a low coercivity, preferably less than 80 A/m, more preferentially less than 70 A/m, e.g. between 20 and 70 A/m, preferentially less than 10 A/m, and even more preferentially less than 3 A/m. The corollary of this relatively low level of coercivity is a relatively high level of magnetic permeability. Therefore, the first ferromagnetic material has advantageously a maximum relative magnetic permeability at least equal to 4,500, preferably at least equal to 5,000, or even 8,000, for example between 5,000 and 50,000, even more preferentially at least equal to 40,000, and even beyond 90,000, so that the first ferromagnetic material shows excellent low-frequency magnetic shielding characteristics.

Advantageously, said first ferromagnetic material of said first layer shows a saturation magnetization of between 0.6 and 1.5 T, preferably between 0.9 and 1.1 T. Thanks to this saturation magnetization level, the first layer provides an optimum electromagnetic shield, it being understood that a high saturation magnetization is generally associated with a high magnetic permeability, which allows the material to more easily conduct the magnetic field lines, which improves its shielding efficiency, including in the presence of strong external magnetic fields.

Advantageously, said first ferromagnetic material has a remanence of between 0.1 and 1 T, preferably between 0.3 and 0.8 T. Such a remanence level also optimizes the electromagnetic shield, by allowing that the first layer does not become itself a significant source of magnetic disturbance once the external field eliminated. It is therefore possible, thanks to the above-mentioned preferential remanence level, to benefit from particularly stable shield properties, even after exposure to strong external magnetic fields.

The values of the above-mentioned parameters (magnetic permeability, saturation magnetization, coercivity, remanence . . . ) are determined by standard measurements, carried out, for example, in accordance with ASTM A773 2021, using, for example, B-H hysteresis cycle plots.

Advantageously, said first ferromagnetic material contains nickel, and preferably a nickel-iron alloy, with for example a mass percentage of between 45 and 80% nickel and between 15 and 55% iron. The use of a nickel-iron alloy makes it possible to achieve, preferably when a nanocrystalline structure is implemented, excellent magnetic properties, corresponding to the different above-mentioned parameter ranges, which provides a high-performance electromagnetic shielding, including when the thickness of the first layer is much less than the thickness of the shielding sheets implemented in the prior art to form shielding cages. Preferably, said Ni-Fe alloy further includes molybdenum Mo (e.g. at most 5% by mass) and manganese Mn (e.g. less than 1% by mass).

For example, the first layer has a thickness of less than 350 μm, preferably less than 300 μm, even more preferentially of between 50 and 250 μm, for example of between 100 and 200 μm. The use of such a thickness leads, advantageously in combination with the other above-mentioned characteristics, to a particularly efficient shielding effect, without weighing down the vibratory mechanical inertial sensor 1.

Advantageously, the ferromagnetic material has a density that is between 8 and 9 g/cm³, preferably between 8.4 and 8.8 g/cm³, which puts it on a par with alloys conventionally used in sheets for shielding cages.

Advantageously, during said first deposition operation, said first layer of the first ferromagnetic material is electrodeposited on part at least of said cover 100 and/or on part at least of said base 2. In other words, the first deposition operation may consist of:
electrodepositing the first layer on part at least of cover 100, during a first sub-operation of galvanic deposition of the first layer on cover 100; and/or
electrodepositing the first layer on part at least of base 2, during a second sub-operation of galvanic deposition of the first layer on base 2,
said first and second sub-operations for depositing the first layer can be carried out together or separately.

Advantageously, during said first deposition operation, and more precisely during said first deposition sub-operation, said first layer is electrodeposited on cover 100, preferably on a single of the inner 110 and outer 120 faces of cover 100. Preferably, said first layer of the first ferromagnetic material is electrodeposited over at least part of the external face 120 during said first deposition operation. Preferably, said first layer is deposited on the outer face 120 but not on the inner face 110. It turns out that depositing the first layer on just one face of cover 100 is sufficient to achieve the desired shielding effect. Moreover, it is sufficient to place a masking cover over and against the edge 100B (as shown in FIGS. 1 to 8) to prevent the electrodeposition of a layer of ferromagnetic material on the inner face 110, which facilitates the implementation of the first deposition operation, with respect to covering only the inner face and not the outer face.

For example, the first deposition operation is carried out before the step of assembling cover 100 to base 2, so that the first operation of depositing the first layer is made on cover 100 and/or on base 2 whereas cover 100 is separated from base 2, which facilitates the first deposition operation and optimizes the quality thereof. It is, however, perfectly conceivable that the first deposition operation is carried out after formation of the casing by assembling cover 100 and base 2.

In accordance with the embodiments of FIGS. 1 to 8, the first layer of the first ferromagnetic material is electrodeposited, during said first deposition operation, over the whole cylindrical side wall 100A of cover 100, on the outer face 120, except in said end zone Z2, thanks for example to a temporary masking deposited on the end zone Z2 to prevent the deposition of the first layer of the ferromagnetic material on the end zone Z2. In the embodiments of FIGS. 1 to 8, the absence of the first layer at the end zone Z2 makes said welding or brazing operation easier and more reliable, thus allowing said welding or brazing bead connecting base 2 and the end zone Z2 to adhere directly to the material forming cover 100, without interposition, between the bead and said cover 100, of the first layer, which could adversely affect the adhesion and reliability of said welding or brazing bead. For a similar reason, said first layer is advantageously electrodeposited, during said first deposition layer, over the whole bottom wall 100C of cover 100, on the outer face 120, except in a vacuum zone Z3 at which said suction orifice is intended to be made through the bottom wall 100C, said vacuum zone Z3 being intended to then receive said welding or brazing pad that closes the suction orifice. Therefore, said welding or brazing pad adheres directly to the material forming cover 100, without interposing the first layer that could adversely affect the adhesion and robustness of said welding or brazing pad.

Advantageously, during said first deposition operation, and more precisely during said second deposition sub-operation, said first layer is electrodeposited on part at least of said base 2. Preferably, the first layer is uniform, i.e. the characteristics of the first layer are constant over the whole surface covered, whether it is the surface of base 2 or that of cover 100. This means that the composition, the physico-chemical properties (in particular, the magnetic properties), the structure and the thickness are advantageously the same everywhere on the surface of the sensitive element, and more precisely the casing.

Advantageously, said second sub-operation of depositing the first layer on base 2 is carried out before said step of assembling cover 100 to said base 2. Therefore, the first layer of said first ferromagnetic material can be electrodeposited on base 2 taken separately, before its assembly with cover 100, which may facilitate implementation of manufacturing method. Possibly, said second deposition sub-operation is carried out before the step of associating test body 3 to base 2, which makes it possible, in particular in the embodiments of FIGS. 1 to 8, to make the manufacturing method simpler and more reliable.

For example, said first layer is electrodeposited, during said first deposition operation, over the whole base 2, except on at least one portion of the latter, which is intended to be located inside the casing, and which includes said fastening zone Z1 (embodiments of FIGS. 1 to 8). For example, said portion that includes said fastening zone Z1 is covered with a temporary mask during said second sub-operation of galvanic deposition of said first layer, so as not to be covered with said first layer. The temporary mask may simply consist of an adhesive protective film, which prevents the zone concerned from being electroplated, and can then be removed after the second deposition sub-operation has been completed. This ensures particularly reliable and durable attachment of test body 3 to base 2, e.g. by welding or brazing (FIGS. 1 to 8), or thermocompression (FIG. 9), by avoiding the interposition, between the material of base 2 and that of central foot 30 of silicon wafer 3B, of the first layer of the first ferromagnetic material, which could interfere with the soldering or welding of foot 30 to base 2 (FIGS. 1 to 8), or with the thermocompression of silicon wafer 3B to base 2 (FIG. 9).

Advantageously, the first layer of ferromagnetic material does not cover the electrically conductive rods 40, 41, 42, 43, 44, 45, 46, 47, 60, 61, 62 (as well as those that are not shown in the figures but can be deduced from the previous ones by symmetry) in order precisely not to impair the performance of the subsequent operations for welding these rods to electronic elements or to connectors. For that purpose, said rods 40, 41, 42, 43, 44, 45, 46, 47, 60, 61, 62 (as well as those that are not shown in the figures but can be deduced from the previous ones by symmetry) are preferentially covered with a temporary mask during said first deposition operation (and more precisely during said second deposition sub-operation), in order not to be covered by said first layer of ferromagnetic material. The temporary mask can for example be in the form of a peelable adhesive element that prevent the electroplating of the conductive rods during the first operation of galvanic deposition, as regards both the portion of rods that is intended to project inside the casing and that which is intended to project out of the casing.

In the particular embodiments of FIGS. 1 to 8, the first operation of depositing the first layer of the first ferromagnetic material thus includes for example:
the first sub-operation of depositing, by galvanoplasty, the first layer of the first ferromagnetic material on substantially all the outer face 120 of cover 100, except the end zone Z2 and the vacuum zone Z3;
the second sub-operation of depositing, by galvanoplasty, the first layer of said first ferromagnetic material on base 2, except on said portion including the fastening zone Z1, while taking care to prevent the electrically conductive rods 40, 41, 42, 43, 44, 45, 46, 47, 60, 61, 62 (as well as those that are not shown in the figures but can be deduced from the previous ones by symmetry) are covered by said first layer, if said rods have been previously associated with base 2, before the second deposition sub-operation; preferably, the first layer has a uniform thickness, identical on cover 100 and base 2, for example between 50 and 250 μm, and implements the same first ferromagnetic material everywhere, which is preferably a nickel-iron alloy, for example with a nanocrystalline structure.
the step of fastening resonator 3A to base 2, for example by welding or brazing;
the step of assembling cover 100 to base 2, for example by brazing or welding;
the vacuum step by sucking out the air contained in the casing, via an orifice formed through cover 100, which is then immediately sealed, for example by a welding or brazing pad.

At the end of the method, a vibratory mechanical inertial sensor 1 is obtained, which is provided with a high-performance electromagnetic shielding, in particular against low-frequency external electromagnetic fields.

In the embodiment of FIG. 9, in which the casing is housed within a closed outer envelope 80, beyond the previous steps of galvanoplasty on base 2 and cover 100, said step of magnetically shielding the casing advantageously includes a primary step of depositing, by galvanoplasty, a primary layer of said first ferromagnetic material on part at least of said outer envelope 80, and for example over the whole outer surface of the outer envelope 80, formed by assembly of the support 80A and the cover 80B. This makes it possible to obtain an optimum magnetic shield, by combining the first layer of ferromagnetic material deposited on the casing formed by the assembly of base 2 and cover 100, and the primary layer of ferromagnetic material deposited on outer envelope 80. Said primary operation of galvanic deposition of the primary layer on outer envelope 80 may be preceded by an operation of depositing a primer layer on the surface to be coated of outer envelope 80, in particular in the latter is made of a ceramic material, as contemplated hereinabove.

In order to further improve the shielding performance, while preserving the compactness and lightweight of the inertial sensor 1, said magnetic shielding step advantageously includes:
a second operation of depositing, preferably by galvanoplasty, a second layer of a second diamagnetic or paramagnetic material, for example copper-based, which further enables a better conduction of heat and optimizing the reduction of the temperature gradients at the sensitive element, on said first layer of the first ferromagnetic material, and
a third operation of depositing, preferably by galvanoplasty, a third layer of a third ferromagnetic material, on said second layer of the second diamagnetic or paramagnetic material.

In this preferential embodiment, the method according to the invention leads to the production of a multi-layer shield, formed by stacking at least the first layer, the second layer and the third layer.

Such an arrangement is particularly interesting because it provides better magnetic shielding than a layer of the same thickness made solely of the first ferromagnetic material. It has indeed been identified that, when a homogeneous layer of a ferromagnetic material of a given thickness is implemented for magnetically shielding the sensitive element of the vibratory mechanical inertial sensor 1, only a portion of the thickness of this layer actually efficiently deviates the magnetic lines of field. It is thus more interesting to implement a plurality of layers of ferromagnetic materials of less thickness, separated from each other by a layer of diamagnetic or paramagnetic material. Preferably, the second layer of the second diamagnetic or paramagnetic material has a thickness of between 50 and 400 μm, preferably of between 50 and 300 μm, for example about 100 μm.

For example, said second and third deposition operations are carried out before said step of assembling said cover 100 to said base 2 (as for example in the embodiments of FIGS. 1 to 8).

The third ferromagnetic material is advantageously identical to the first ferromagnetic material, so that the third deposition operation consists in this case in depositing a third layer of the first ferromagnetic material on said second layer. Advantageously, the third layer has a thickness of less than 350 μm, preferably less than 300 μm, even more preferentially of between 50 and 250 μm, for example between 100 and 200 μm. In a particularly advantageous embodiment, the first layer is formed of a first ferromagnetic material consisted of a nickel-iron alloy with, for example, a nickel mass percentage of between 45 and 79% and an iron mass percentage of between 15 and 55%, and further includes molybdenum Mo (at most 5% by mass) and manganese Mn (less than 1% by mass). The thickness of the first layer is for example of about 150 μm. The third layer is substantially identical to the first layer, i.e. it is formed of the same ferromagnetic material as mentioned hereinabove and has a similar thickness of 150 μm. Finally, the second layer is preferably formed of a diamagnetic material, for example copper or a copper alloy that further allows better conduction of heat and optimizing the reduction of the temperature gradients at the sensitive element. A three-layer shield is thus obtained of total thickness substantially equal to 0.5 mm, whose shielding performance is higher than that of a layer that would be formed only of the same ferromagnetic material as that of the first and third layers and that would have a same total thickness of 0.5 mm. It is therefore possible, in this particular embodiment, to optimize the shield efficiency for a same given maximum thickness.

Advantageously, the second and third deposition operations are repeated alternately to form a stack of alternated layers of ferromagnetic material and diamagnetic or paramagnetic material, to thus form a stack of electrodeposited layers of ferromagnetic material separated from each other by electrodeposited layers of diamagnetic or paramagnetic material. The invention thus advantageously implements a uniform coating at the surface of the casing, which can be either a simple layer (single-layer) of a ferromagnetic material, deposited by galvanoplasty, or a stack of alternated layers of ferromagnetic and diamagnetic (or paramagnetic) material, all deposited by galvanoplasty, in order to form a multi-layer shield.

As mentioned hereinabove, the invention also relates as such to a vibratory mechanical inertial sensor 1 that can be manufactured by the method according to the previous description, said vibratory mechanical inertial sensor 1 comprising at least a base 2, a test body 3 attached to base 2 and designed to vibrate and/or deform and/or move, as well as a cover 100 that covers test body 3 and forms with base 2 a casing that delimits an inner space within which test body 3 is housed, said inner space being vacuumed or filled with a dry gas, said casing being at least partly coated with a first layer of a first ferromagnetic material deposited by galvanoplasty, to form a magnetic shield of said casing.

As exposed hereinabove, the vibratory mechanical inertial sensor 1 advantageously forms a vibratory gyroscopic sensor (FIGS. 1 to 8), said test body 3 being in this case formed by a resonator 3A, which comprises for example a vibrating cylinder 31 (FIGS. 1 to 7) or a vibrating hemispherical shell 32 (FIG. 8).

In another embodiment, the vibratory mechanical inertial sensor 1 forms a vibrating beam accelerometer (VBA) of the micro-electro-mechanical system (MEMS) type, in which case test body 3 is advantageously formed by a test mass that is for example made by micro-machining a silicon or quartz wafer 3B. In this latter embodiment, the vibratory mechanical inertial sensor 1 preferentially comprises, as exposed hereinabove in relation with the method, an outer envelope 80 within which the casing is encapsulated, as illustrated in FIG. 9. Said outer envelope 80 is at least partly coated in this case with a primary layer of said first ferromagnetic material deposited by galvanoplasty, to optimize the magnetic shield, with possibly a primer layer interposed between the outer envelope 80 and the primary layer to help it adhere to the outer envelope 80, in particular if the latter is made of a ceramic material, for example. Therefore, in the particular embodiment of FIG. 9, the vibratory mechanical inertial sensor 1 preferentially comprises a casing at least partly coated with a first layer of a first ferromagnetic material deposited by galvanoplasty, as well as an outer envelope 80 within which the casing is encapsulated, said outer envelope 80 is also advantageously coated with the first ferromagnetic material deposited by galvanoplasty.

The invention finally also relates as such to an inertial unit that includes at least one plate 4, as well as at least one vibratory mechanical inertial sensor 1 according to the invention. Said plate 4 is provided with at least one support 50 to which is attached said vibratory mechanical inertial sensor 1 to be immobilized relative to said plate 4. For example, in the embodiment illustrated in the figures, support 50 is in the form of a one-piece part extending plate 4 or a ring attached to plate 4 and into which is inserted cover 100 of a vibratory mechanical inertial sensor 1. The ring forming support 50 can for example further comprise fastening orifices 500, 501, 502, 503 coming in correspondence with the respective orifices formed by the fastening lugs 200, 210, 220, 230 (embodiment of FIGS. 1 to 7), to allow for example base 2 to be screwed to support 50. Advantageously, the plate is provided, in addition to support 50, with two other supports 51, 52 that are similar thereto and to which are respectively attached to other vibratory mechanical inertial sensors according to the invention. Said supports 50, 51, 52 are arranged perpendicular to each other along respectively the three directions in space, in such a way that the three vibratory mechanical inertial sensors according to the invention carried by the inertial unit are arranged so that their respective central axis Z-Z′ extends along a direction in space that is perpendicular to the two other directions in space. Preferably, the inertial unit according to the invention receives, in addition to three vibratory gyroscopic sensors according to the invention, for example in accordance with the embodiment of FIGS. 1 to 7, three vibrating beam accelerometers (VBA) in accordance with the invention, for example in accordance with the embodiment of FIG. 9, said accelerometers being arranges respectively along three directions in space.

The inertial unit further includes a cover 5 that covers said at least one vibratory mechanical inertial sensor 1 (and for a navigation system, at least six vibratory mechanical inertial sensors arranged perpendicular to each other and providing accelerometric and gyroscopic measurement functions according to an orthogonal trihedron) and that is attached to plate 4, for example by screwing, to form with the latter an enclosure within which is housed said at least one vibratory mechanical inertial sensor 1 (herein the six vibratory mechanical inertial sensors). Said enclosure is at least partly coated with a secondary layer of said first ferromagnetic material deposited by galvanoplasty. Preferably, the secondary layer is deposited by galvanoplasty in the same way and according to a method identical to that implemented to deposit said first and/or said third layer. Said secondary layer is preferably substantially similar to said first and/or said third layer, both as regards its thickness and its micro-structure and its physico-chemical characteristics, and in particular its magnetic characteristics. Therefore, the invention makes it possible to cumulate a double shield, i.e. that which is directly deposited on each vibratory mechanical inertial sensor 1 of the inertial unit, and that which is directly deposited on the enclosure of the inertial unit, which offers an excellent shielding performance while keeping controlled size and weight, as well as an easy, fast and cheap manufacturing and assembling method.

It is also perfectly conceivable to deposit on the secondary layer a tertiary layer of diamagnetic or paramagnetic material, for example by galvanoplasty, and to then deposit on this tertiary layer, here again preferably by galvanoplasty, a quaternary layer of a fourth ferromagnetic material, which is for example identical to the first ferromagnetic material. In this way, a stack of layers is formed, offering the same advantages as those already set out hereinabove in relation to the description of the manufacturing method.

Advantageously, plate 4 has an inner face 4A that carries support 50 and is directed towards the inside of the enclosure, as well as an opposite, outer face 4B, whereas cover 5 has an inner face 5A directed towards the inside of the enclosure, and thus towards the inner face 4A of plate 4, and an opposite, outer face 5B. Advantageously, said secondary layer is electrodeposited on the inner face of plate 4, as well as, preferably, on each support 50, 51, 52, in order to form a shield located as close as possible to each inertial sensor 1 mounted inside the enclosure. However, said secondary layer is not deposited on the outer face 4B of plate 4, in order not to be exposed to risk of mechanical, chemical or thermal degradation coming from the external environment. Likewise, said secondary layer is advantageously deposited on the inner face 5A of cover 5, but not on the outer face 5B thereof, which here again makes it possible to place the shielding layer at close as possible to each vibratory mechanical inertial sensor 1 contained in the enclosure, by avoiding that the secondary layer is exposed directly to the external environment and to the risks of degradation that ensue therefrom.

1. A method for manufacturing a vibratory mechanical inertial sensor (1), comprising a step of associating a test body (3) with a base (2), said test body (3) being designed to vibrate and/or deform and/or move, said method further comprising a step of assembling a cover (100) to said base (2) so that said cover (100) covers the test body (3) and forms with the base (2) a casing within which said test body (3) is housed, a step of vacuuming said casing or filling said casing with a dry gas, and a step of magnetically shielding said casing, which includes a first operation of depositing, by galvanoplasty, a first layer of a first ferromagnetic material on part at least of said casing.

2. The method according to claim 1, characterized in that said first ferromagnetic material is a material with a nanocrystalline structure.

3. The method according to claim 2, characterized in that said nanocrystalline structure has a mean grain size of between 5 and 100 nm, preferably between 5 and 50 nm, more preferentially between 10 and 30 nm.

4. The method according to claim 1, characterized in that said first ferromagnetic material contains nickel.

5. The method according to claim 4, characterized in that said first ferromagnetic material is a nickel-iron alloy, with for example a mass percentage of between 45 and 80% nickel and between 15 and 55% iron.

6. The method according to claim 1, characterized in that said first layer has a thickness of less than 350 μm, preferably less than 300 μm, even more preferentially of between 50 and 250 μm, for example of between 100 and 200 μm.

7. The method according to claim 1, characterized in that said first ferromagnetic material has a density that is between 8 and 9 g/cm³, preferably between 8.4 and 8.8 g/cm³.

8. The method according to claim 1, characterized in that said first ferromagnetic material has a maximum relative magnetic permeability at least equal to 4,500, preferably at least equal to 5,000, or even more preferentially at least equal to 8,000, for example at least equal to 40,000.

9. The method according to claim 1, characterized in that said first ferromagnetic material shows a saturation magnetization of between 0.6 and 1.5 T, preferably between 0.9 and 1.1 T.

10. The method according to claim 1, characterized in that said first ferromagnetic material has a coercivity of less than 80 A/m, preferably less than 70 A/m, even more preferentially less than 10 A/m, advantageously less than 3 A/m.

11. The method according to claim 1, characterized in that said first ferromagnetic material has a remanence of between 0.1 and 1 T, preferably between 0.3 and 0.8 T.

12. The method according to claim 1, characterized in that, during said first deposition operation, said first layer of the first ferromagnetic material is electrodeposited on part at least of said cover (100) and/or on part at least of said base (2).

13. The method according to claim 1, characterized in that said first deposition operation is carried out before said step of assembling said cover (100) to said base (2).

14. The method according to claim 1, characterized in that said cover (100) has an inner face (110) intended to face the inside of the casing and an opposite, outer face (120), said first layer of the first ferromagnetic material being electrodeposited on at least a portion of said outer face (120) during said first deposition operation.

15. The method according to claim 14, characterized in that, during said first deposition operation, said first layer is electrodeposited on said outer face (120) but not on said inner face (110).

16. The method according to claim 15, characterized in that said cover (100) is bell-shaped, with a cylindrical side wall (100A) having a free edge (100B), said step of assembling the cover (100) to the base (2) including a docking operation so that the free edge (100B) comes into contact with said base (2) and a welding or brazing operation to make a welding or brazing bead linking the base (2) to an end zone (Z2) of the cylindrical side wall (100A) located near the free edge (100B) on the outer face (120), said first layer being electrodeposited, during said first deposition operation, over the whole cylindrical side wall (100A), on the outer face (120), except in said end zone (Z2).

17. The method according to claim 1, characterized in that said vibratory mechanical inertial sensor (1) is a vibratory gyroscopic sensor, said test body being formed by a resonator (3A), said resonator (3A) comprising, for example, a vibrating cylinder (31) or a vibrating hemispherical shell (32).

18. The method according to claim 17, characterized in that it comprises a step of associating at least one excitation device to said resonator (3A) to vibrate it, as well as a step of associating at least one detection device to said resonator (3A) to detect vibrations of said resonator (3A).

19. The method according to claim 1, characterized in that said vibratory mechanical inertial sensor (1) is a vibrating beam accelerometer (VBA), for example of the micro-electro-mechanical system (MEMS) type, said test body (3) being formed by a test mass that is for example made by micro-machining a silicon wafer (3B).

20. The method according to claim 19, characterized in that said base (2) and cover (100) are formed respectively by a first and a second support part (2000, 1000) made of glass or silicon.

21. The method according to claim 19, characterized in that it comprises a step of encapsulating the casing in an outer envelope (80), said step of magnetically shielding said casing including a primary step of depositing, by galvanoplasty, a primary layer of said first ferromagnetic material on part at least of said outer envelope (80).

22. The method according to claim 1, characterized in that said magnetic shielding step includes:
a second operation of depositing, preferably by galvanoplasty, a second layer of a second diamagnetic or paramagnetic material, for example copper-based, on said first layer of the first ferromagnetic material, and
a third operation of depositing, preferably by galvanoplasty, a third layer of a third ferromagnetic material, on said second layer of the second diamagnetic or paramagnetic material.

23. The method according to claim 22, characterized in that said second and third deposition operations are carried out before said step of assembling said cover (100) to said base (2).

24. The method according to claim 22, characterized in that said second layer of the second diamagnetic or paramagnetic material has a thickness of between 50 and 400 μm, preferably between 50 and 300 μm.

25. The method according to claim 22, characterized in that said third ferromagnetic material is identical to said first ferromagnetic material.

26. The method according to claim 22, characterized in that said third layer has a thickness of less than 350 μm, preferably less than 300 μm, even more preferentially of between 50 and 250 μm, for example between 100 and 200 μm.

27. The method according to claim 22, characterized in that said second and third deposition operations are repeated alternately to form a stack of alternated layers of ferromagnetic material and diamagnetic or paramagnetic material.

28. A vibratory mechanical inertial sensor (1) that can be manufactured by a method according to claim 1, said vibratory mechanical inertial sensor (1) comprising at least a base (2), a test body (3) attached to said base (2) and designed to vibrate and/or deform and/or move, as well as a cover (100) that covers said test body (3) and forms with the base (2) a casing that delimits an inner space within which said test body (3) is housed, said inner space being vacuumed or filled with a dry gas, said casing being at least partly coated with a first layer of a first ferromagnetic material deposited by galvanoplasty, to form a magnetic shield of said casing.

29. The vibratory mechanical inertial sensor (1) according to claim 28, characterized in that it forms a vibratory gyroscopic sensor, said test body (3) being formed by a resonator (3A), said resonator (3A) comprising for example a vibrating cylinder (31) or a vibrating hemispherical shell (32).

30. The vibratory mechanical inertial sensor (1) according to claim 28, characterized in that it forms a vibratory accelerometer, for example of the micro-electro-mechanical system (MEMS) type, said test body (3) being formed by a test mass that is for example made by micro-machining a silicon wafer (3B).

31. The vibratory mechanical inertial sensor (1) according to claim 30, characterized in that it comprises an outer envelope (80) within which said casing is encapsulated, said outer envelope (80) being at least partly coated with a primary layer of said first ferromagnetic material deposited by galvanoplasty.

32. An inertial unit including at least one plate (4) as well as at least one vibratory mechanical inertial sensor (1) according to claim 28, said plate (4) being provided with at least one support (50) to which is attached said vibratory mechanical inertial sensor (1) to be immobilized relative to said plate (4), said central unit further including a cover (5) that covers said vibratory mechanical inertial sensor (1) and that is attached to the plate (4) to form with the latter an enclosure within which is housed said at least one vibratory mechanical inertial sensor (1), said enclosure being at least partly coated with a secondary layer of said first ferromagnetic material deposited by galvanoplasty.

33. The inertial unit according to claim 32, characterized in that said plate (4) has an inner face (4A) that carries the support (50) and is directed towards the inside of the enclosure, and an opposite, outer face (4B), whereas the cover (5) has an inner face (5A) directed towards the inside of the enclosure, and an opposite, outer face (5B), said secondary layer being deposited on said inner faces (4A, 5A) of the plate (4) and the cover (5), but not on the outer faces (4B, 5B) thereof.
